(19) United States
(12) Patent Application Publication
(10) Pub. No.: US 2012/0149210 A1
(43) Pub. Date: Jun. 14, 2012

(54) SYSTEMS, APPARATUSES, AND METHODS FOR CHEMICALLY PROCESSING SUBSTRATES USING THE COANDA EFFECT

(76) Inventors: Ronald L. COLVIN, Gilbert, AZ (US); Dennis GOODWIN, SR., Happy Jack, AZ (US); Jeff MITTENDORF, Chandler, AZ (US); Charles J. MORETTI, Scottsdale, AZ (US); John W. ROSE, Cave Creek, AZ (US); Earl Blake SAMUELS, Scottsdale, AZ (US)

(21) Appl. No.: 13/194,947

(22) Filed: Jul. 30, 2011

Related U.S. Application Data
(60) Provisional application No. 61/369,072, filed on Jul. 30, 2010.
(60) Provisional application No. 61/369,077, filed on Jul. 30, 2010.

(51) Int. Cl. H01L 21/31; B05D 5/12; C23C 16/00

(52) U.S. Cl. 438/758; 118/728; 427/58; 257/E21.24

(57) ABSTRACT

A system for processing substrates is described. In one embodiment, the system comprises a process chamber and at least one Coanda effect gas injector. The at least one Coanda effect gas injector is disposed proximate a location for the peripheral edge of the substrate so as to provide a Coanda effect gas flow over the surface of the substrate. Apparatuses and methods are also described.

### CROSS-REFERENCE TO RELATED APPLICATIONS

The present application claims benefit of U.S. Patent Application Ser. No. 61/369,072, Docket No. LAS-003, titled “SYSTEMS, APPARATUSES, AND METHODS FOR CHEMICALLY PROCESSING SUBSTRATES USING THE COANDA EFFECT,” to Ronald L. Colvin et al., filed Jul. 30, 2010. The present application is related to: U.S. patent application Ser. No. 13/193,498, filed Jul. 28, 2011; U.S. Patent Application Ser. No. 61/369,047, Docket No. LAS-001, titled “SUBSTRATE PROCESSING APPARATUSES AND SYSTEMS,” to Ronald L. Colvin et al., filed Jul. 29, 2010; U.S. Patent Application Ser. No. 61/369,077, Docket No. LAS-002, titled “ELECTRICAL RESISTANCE HEATER AND HEATER ASSEMBLIES,” to Ronald L. Colvin et al., filed Jul. 30, 2010; U.S. Pat. No. 6,331,212, filed 17 Apr. 2000; and U.S. Pat. No. 6,774,060, filed 7 Jul. 2001. The contents of all of these applications and patents are incorporated herein in their entirety by this reference.

### BACKGROUND

This invention relates to systems, apparatuses, and methods for processing substrates; more particularly, chemically processing substrates for electronic devices and optical-electronic devices.

Chemical processing of substrates is used in numerous applications such as modern microelectronic device manufacturing. These processes include processes such as chemical vapor deposition (CVD) and epitaxial semiconductor deposition such as silicon epitaxy, silicon germanium epitaxy, and compound semiconductor epitaxy. These processes are typically performed using one or more gases for causing reactions on the surface of substrates such as semiconductor wafers, flat panel display substrates, solar cell substrates, and other substrates.

### SUMMARY

This invention seeks to provide systems, apparatuses, and methods that may overcome one or more deficiencies in methods and apparatus for chemically processing substrates. One aspect of the invention is a system for processing substrates. The system comprises a process chamber; a substrate support disposed in the process chamber; and at least one Coanda effect gas injector disposed proximate a peripheral edge of the substrate support so as to provide a Coanda effect gas flow over the surface of the substrate(s) and/or substrate support.

Another aspect of the invention is a method of performing a chemical reaction on a substrate. The method comprises providing a substrate; providing one or more reactive gases; and creating a Coanda effect gas flow of the one or more reactive gases over the substrate.

It is to be understood that the invention is not limited in its application to the details of construction and to the arrangements of the components set forth in the following description or illustrated in the drawings. The invention is capable of other embodiments and of being practiced and carried out in various ways. In addition, it is to be understood that the phraseology and terminology employed herein are for the purpose of description and should not be regarded as limiting.

### BRIEF DESCRIPTION OF THE DRAWINGS

FIG. 1 is a cross-section side view of an embodiment of the present invention.

FIG. 2 is a cross-section side view of an embodiment of the present invention.

FIG. 3 is a cross-section side view of an embodiment of the present invention.

FIG. 4 is a top view of an apparatus for an embodiment of the present invention.

FIG. 4-1 is a cross-section side view of the apparatus shown in FIG. 4.

FIG. 5 is a top view of an apparatus for an embodiment of the present invention.

FIG. 5-1 is a cross-section side view of the apparatus shown in FIG. 5.

FIG. 6 is a top view of an apparatus for an embodiment of the present invention.

FIG. 6-1 is a cross-section side view of the apparatus shown in FIG. 6.

FIG. 7 is a cross-section top view of an embodiment of the present invention.

FIG. 8 is a process diagram of an embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DESCRIPTION

For the following defined terms, these definitions shall be applied, unless a different definition is given in the claims or elsewhere in this specification. All numeric values are herein defined as being modified by the term “about,” whether or not explicitly indicated. The term “about” generally refers to a range of numbers that a person of ordinary skill in the art would consider equivalent to the stated value to produce substantially the same properties, function, result, etc.

The operation of embodiments of the present invention will be discussed below in the context of the deposition of an epitaxial layer of doped silicon on a silicon wafer. It is to be understood, however, that embodiments in accordance with the present invention may be used to perform essentially any substrate processing that may benefit from layer thickness uniformity and composition uniformity across the substrate. As examples, embodiments of the present invention may include equipment and/or processes for depositing layers of materials such as gallium nitride, gallium arsenide, silicon germanium, gallium aluminum arsenide, indium phosphide, cadmium telluride, mercury cadmium telluride, silicon carbide, silicon nitride, silicon dioxide, doped silicon oxide, boron phosphorus silicate glass, phosphorus silicate glass, and others.

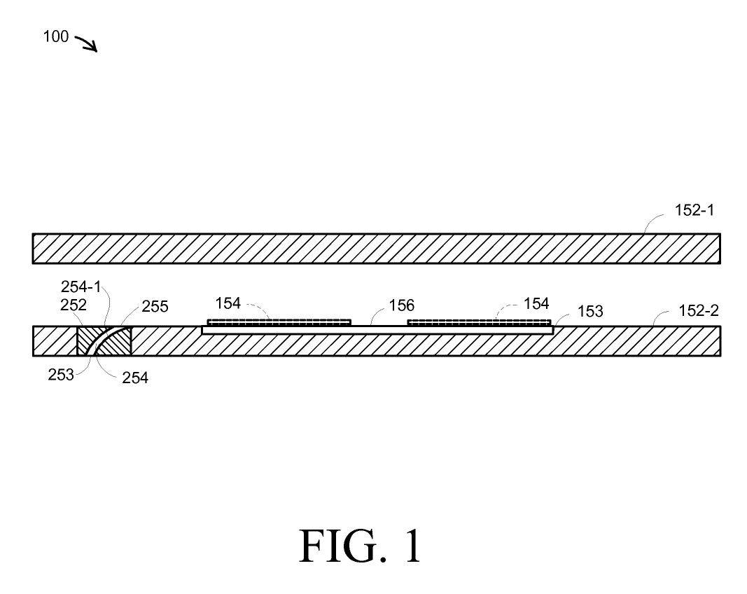

Reference is now made to FIG. 1 where there is shown a cross-section side view of a system 100 according to an embodiment of the present invention. System 100 comprises a process chamber having a top surface 152-1 and a bottom surface 152-2 substantially as shown in FIG. 1. Optionally, one or more substrates 154 (position of substrates shown as broken lines) may be placed on the bottom of the process chamber for processing. Alternatively, system 100 includes a substrate holder 156 disposed so as to hold one or more substrates 154 in the process chamber. As an option for some embodiments of the present invention, bottom surface 152-2 of the process chamber has a recessed area 153 that at least partially contains substrate holder 156. System 100 comprises at least one Coanda effect gas injector 252 disposed proximate a peripheral edge of substrate support 156 so as to provide a Coanda effect gas flow over the surface of substrate support 156 and/or the one or more substrates 154. According to some embodiments of the present invention, system 100 further comprises a gas flow control system (not shown in FIG. 1) in fluid communication with the at least one Coanda effect gas injector 252 so as to provide one or more reactive gases to the at least one Coanda effect gas injector 252.

In one embodiment of system 100, Coanda effect gas injector 252 has a gas entry port 253, a gas flow channel 254, and a gas exit port 255. Gas exit port 255 is in fluid communication with gas flow channel 254, and gas flow channel 254 is in fluid communication with the gas entry port 253. Gas flow channel 254 is formed by a convex surface 254-1 of Coanda effect gas injector 252 to produce the Coanda effect gas flow. More specifically, convex surface 254-1 is formed and disposed so as to tangentially approach a plane located approximately at the surface of substrates 154 and/or the surface of substrate holder 156. Convex surface 254-1, according to one embodiment of the present invention, is a curved surface. As an option for other embodiments, convex surface 254-1 is formed by one or more sloping surfaces with little or no curvature for each of the sloping surfaces.

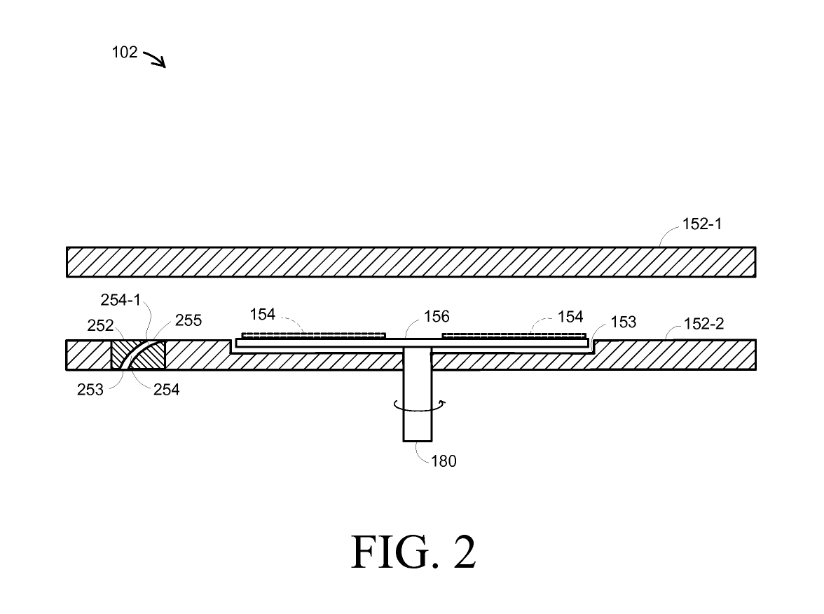

Reference is now made to FIG. 2 where there is shown a cross-section side view of a system 102 according to an embodiment of the present invention. System 102 comprises a process chamber having a top surface 152-1 and a bottom surface 152-2 substantially as shown in FIG. 1. System 102 includes a substrate holder 156 disposed so as to hold one or more substrates 154 in the process chamber. As an option for some embodiments of the present invention, bottom surface 152-2 of the process chamber has a recessed area 153 that at least partially contains substrate holder 156.

System 102 shown in FIG. 2 comprises a rotary coupling 180 connected with substrate holder 156 so as to provide rotation for one or more substrates 154 (position of substrates shown as broken lines). More specifically, system 102 comprises rotary coupling 180 disposed between substrate support 156 and the process chamber for rotating the surface of substrate support 156 and the one or more substrates 154, if present thereon. Alternatively, system 102 may comprise a linear actuator connected with substrate support 156 for linear translation of the surface of substrate support 156.

System 102 comprises at least one Coanda effect gas injector 252 disposed proximate a peripheral edge of substrate support 156 so as to provide a Coanda effect gas flow over the surface of substrate support 156 and/or the one or more substrates 154. According to some embodiments of the present invention, system 102 further comprises a gas flow control system (not shown in FIG. 2) in fluid communication with the at least one Coanda effect gas injector 252 so as to provide one or more reactive gases to the at least one Coanda effect gas injector 252.

In one embodiment of system 102, Coanda effect gas injector 252 has a gas entry port 253, a gas flow channel 254, and a gas exit port 255. Gas exit port 255 is in fluid communication with gas flow channel 254, and gas flow channel 254 is in fluid communication with the gas entry port 253. Gas flow channel 254 is formed by a convex surface 254-1 of Coanda effect gas injector 252 to produce the Coanda effect gas flow. More specifically, convex surface 254-1 is formed and disposed so as to tangentially approach a plane located approximately at the surface of substrates 154 and/or the surface of substrate holder 156. Convex surface 254-1, according to one embodiment of the present invention, is a curved surface. As an option for other embodiments, convex surface 254-1 is formed by one or more sloping surfaces with little or no curvature for each of the sloping surfaces.

The Coanda effect gas flow results from flowing the gas over convex surface 254-1 which induces an attachment between the gas flow and convex surface 254-1 so that the gas flow substantially follows convex surface 254-1. The present inventors have found that the gas leaving Coanda effect gas injector 252 appears to continue the attachment for some distance to include at least part of the surface of substrate holder 156 and/or at least part of the surface of the one or more substrates 154. The present inventors believe that a possible explanation is that the attachment between the gas flow and the surfaces aids in keeping one or more reactive chemicals in the gas flow closer to the surface of the substrate so that the one or more reactive chemicals are more efficiently used for processing the surface of the substrates, or one or more other phenomena may be involved with producing the benefits from the use of the Coanda effect. In other words, the Coanda effect gas flow appears to interact synergistically with the surface of the substrate to keep the one or more reactive chemicals near the surface of the substrate for a longer time interval. Discussions of the Coanda effect can be found in “Applications of the Coanda Effect,” by Imants Reba, Scientific American, Vol. 214, No. 6, June 1966, pages 84-92 and U.S. Pat. No. 2,052,869 to H. Coanda; the content of these documents are incorporated herein by this reference for all purposes.

As an option for some embodiments of the present invention, the at least one Coanda effect gas injector 252 has a gas exit port 255 that is rectangular in shape so as to form a slit. Alternatively, the gas exit port 255 may be square or another geometric shape.

As an option for some embodiments of the present invention, the at least one Coanda effect gas injector 252 is disposed in the process chamber so that gas exit port 255 is substantially coplanar with or above the surface of the one or more substrates 154 and/or substantially coplanar with or above the surface of substrate support 156. As another option, the at least one Coanda effect gas injector 252 is disposed in the process chamber so that gas exit port 255 is substantially coplanar with or above bottom surface 152-2 of the process chamber.

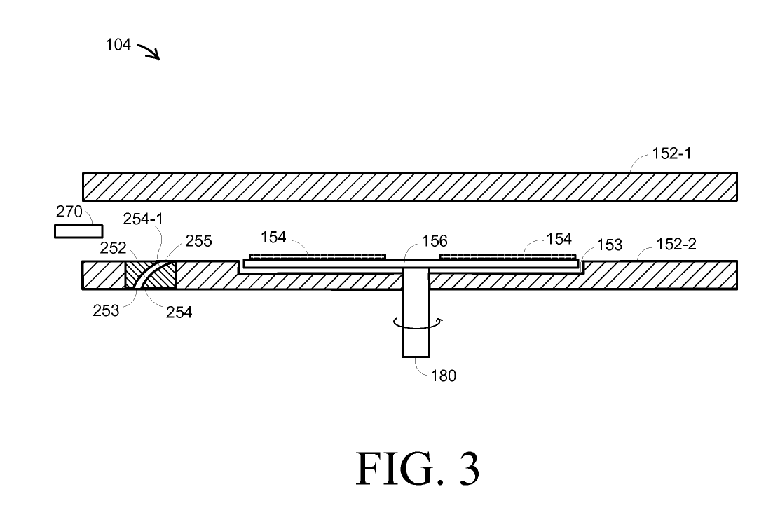

Reference is now made to FIG. 3 where there is shown a cross-section side view of a system 104 according to an embodiment of the present invention. System 104 comprises a process chamber having a top surface 152-1 and a bottom surface 152-2 substantially as shown in FIG. 1. System 104 includes a substrate holder 156 disposed so as to hold one or more substrates 154 in the process chamber. As an option for some embodiments of the present invention, bottom surface 152-2 of the process chamber has a recessed area 153 that at least partially contains substrate holder 156.

System 104 shown in FIG. 3 comprises a rotary coupling 180 connected with substrate holder 156 so as to provide rotation for the one or more substrates 154. More specifically, system 104 comprises rotary coupling 180 disposed between substrate support 156 and the process chamber for rotating the surface of substrate support 156 and the one or more substrates 154, if present thereon. Alternatively, system 104 may comprise a linear actuator connected with substrate support 156 for linear translation of the surface of substrate support 156.

System 104 comprises at least one Coanda effect gas injector 252 disposed proximate a peripheral edge of substrate support 156 so as to provide a Coanda effect gas flow over the surface of substrate support 156 and/or the one or more substrates 154. According to some embodiments of the present invention, system 104 further comprises a gas flow control system (not shown in FIG. 3) in fluid communication with the at least one Coanda effect gas injector 252 so as to provide one or more reactive gases to the at least one Coanda effect gas injector 252.

System 104 comprises at least one secondary gas injector 270 disposed so as to provide one or more gases or gas mixtures between top surface 152-1 and bottom surface 152-2 of the process chamber. More specifically, the at least one secondary gas injector 270 is arranged to flow a gas or gas mixture over substrates 154 and/or substrate support 156. The at least one secondary gas injector 270 is not a Coanda effect gas injector. The at least one secondary gas injector 270 may be a standard gas injector such as those typically used for processing substrates such as a solid body having a borehole for gas flow therethrough, such as a tube, such as a tube having a showerhead or nozzle, or such as another type of nozzle.

System 104 shows an embodiment with the at least one secondary gas injector 270 positioned behind the at least one Coanda effect gas injector 252. It is to be understood that other embodiments of the present invention may have relative positions and orientations of the at least one secondary gas injector 270 and the at least one Coanda effect gas injector 252 different from what is shown in FIG. 3.

A potential benefit may be achieved for some embodiments of the present invention as a result of combining the use of the at least one Coanda effect gas injector 252 and the at least one secondary injector 270. In other words, a synergistic interaction between the gas flow from the at least one Coanda effect gas injector 252 and the gas flow from the at least one secondary injector 270 may yield improved process results.

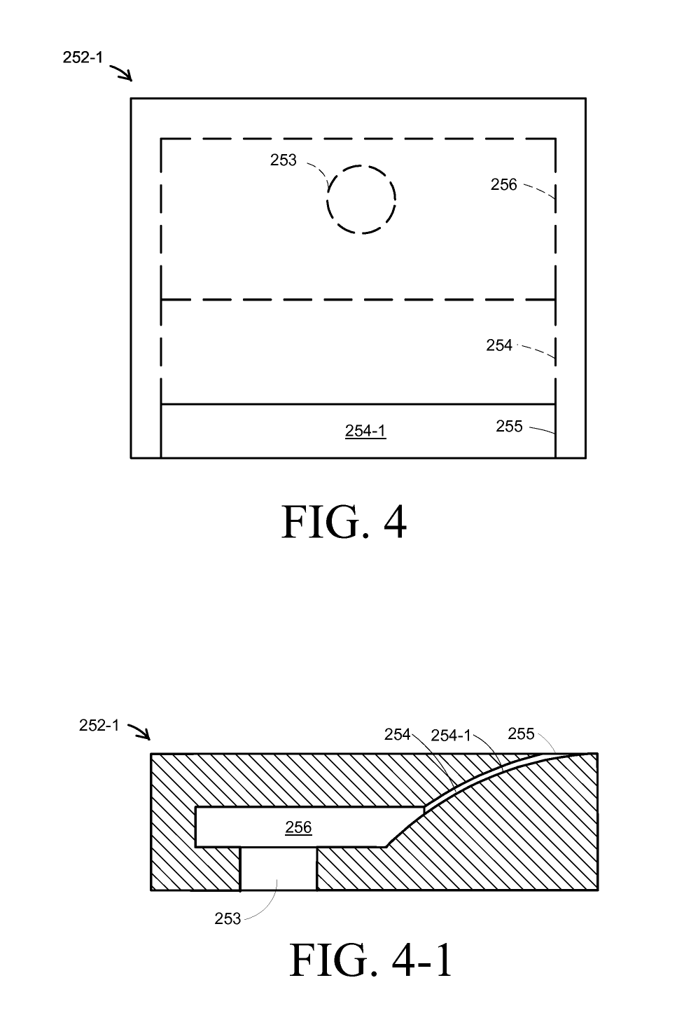

Reference is now made to FIG. 4 and FIG. 4-1 where there is shown a top view and a cross-section side view, respectively, of a Coanda effect gas injector 252-1 for one or more embodiments of the present invention. Broken lines are used to illustrate hidden lines. Coanda effect gas injector 252-1 may be used, as an option, to replace the at least one Coanda effect gas injector 252 described for embodiments of the present invention illustrated in FIG. 1, FIG. 2, or FIG. 3. Coanda effect gas injector 252-1 is similar to the at least one Coanda effect gas injector 252.

Coanda effect gas injector 252-1 is a substantially rigid structure having a gas entry port 253, a gas flow channel 254, and a gas exit port 255. Coanda effect gas injector 252-1 also has a plenum 256 that is not present in the at least one Coanda effect gas injectors 252. Gas exit port 255 is in fluid communication with plenum 256 via gas flow channel 254. Gas entry port 253 is in fluid communication with plenum 256. Gas flow channel 254 is formed by at least one convex surface 254-1 of Coanda effect gas injector 252-1 so as to produce the Coanda effect gas flow.

During operation, Coanda effect gas injector 252-1 receives a gas or a mixture of gases at gas entry port 253, the gas flows into plenum 256 from gas entry port 253 and continues on into gas flow channel 254, passes over convex surface 254-1, and exits at gas exit port 255.

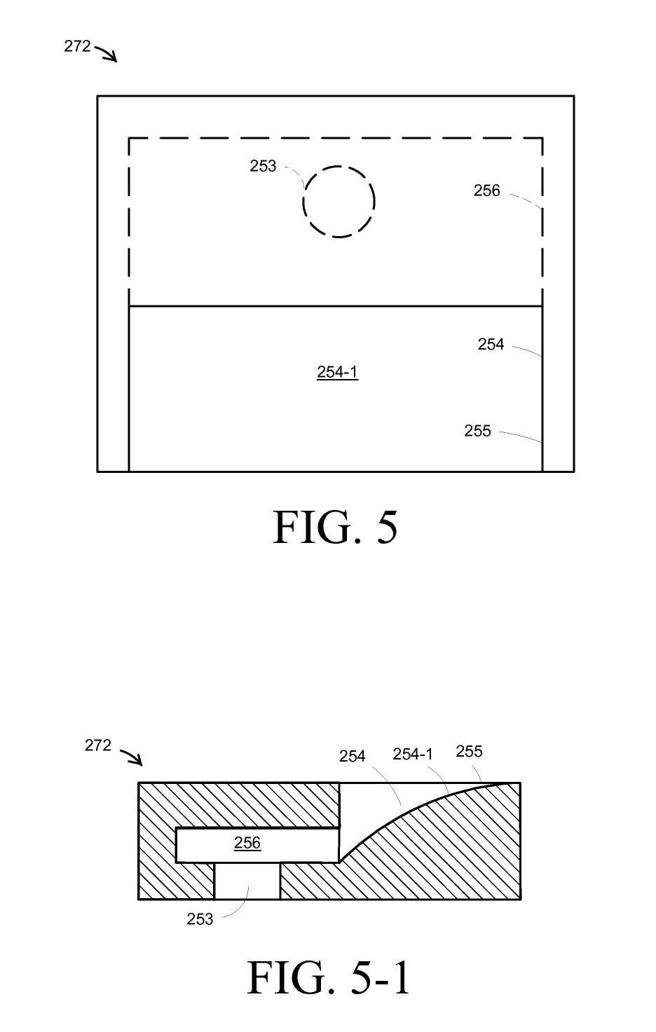

Reference is now made to FIG. 5 and FIG. 5-1 where there is shown a top view and a cross-section side view, respectively, of a Coanda effect gas injector 272 for one or more embodiments of the present invention. Broken lines are used to illustrate hidden lines. Coanda effect gas injector 272 may be used, as an option, to replace the at least one Coanda effect gas injector 252 described for embodiments of the present invention illustrated in FIG. 1, FIG. 2, or FIG. 3. Coanda effect gas injector 272 is similar to the at least one Coanda effect gas injector 252.

Coanda effect gas injector 272 is a substantially rigid structure having a gas entry port 253, a gas flow channel 254, and a gas exit port 255. Coanda effect gas injector 272 optionally has a plenum 256 that is not present in the at least one Coanda effect gas injectors 252. Gas exit port 255 is in fluid communication with plenum 256 via gas flow channel 254. Gas entry port 253 is in fluid communication with plenum 256. Gas flow channel 254 is formed by at least one convex surface 254-1 of Coanda effect gas injector 272 so as to produce the Coanda effect gas flow. Gas exit port 255 for Coanda effect gas injector 272 extends over substantially the entire length of gas flow channel 254. More specifically, FIG. 5 and FIG. 5-1 shows that gas exit port 255 extends back to plenum 256 so that substantially the entire length of convex surface 254-1 is uncovered by gas exit port 255. It is to be understood that other configurations of Coanda effect gas injector 272 can be used in embodiments of the present invention. As examples, alternative embodiments of Coanda effect gas injector 272 may have other dimensions for gas exit port 255 so the other fractions of convex surface 254-1 are uncovered by gas exit port 255.

During operation, Coanda effect gas injector 272 receives a gas or a mixture of gases at gas entry port 253, the gas flows into plenum 256 from gas entry port 253 and continues on into gas flow channel 254, passes over convex surface 254-1, and exits at gas exit port 255 substantially over the entire length of convex surface 254-1.

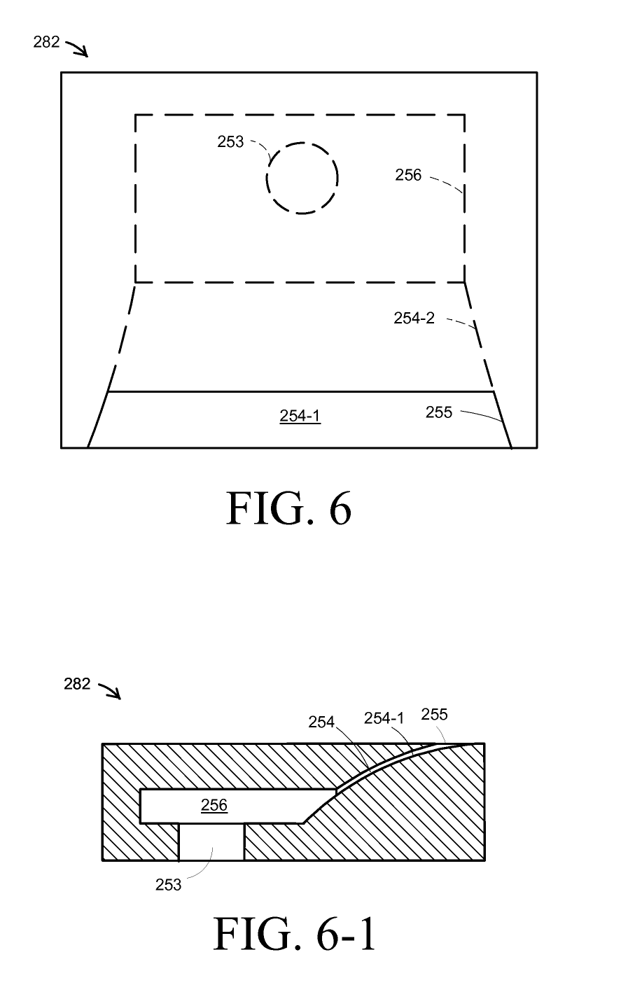

Reference is now made to FIG. 6 and FIG. 6-1 where there is shown a top view and a cross-section side view, respectively, of a Coanda effect gas injector 282 for one or more embodiments of the present invention. Broken lines are used to illustrate hidden lines. Coanda effect gas injector 282 may be used, as an option, to replace the at least one Coanda effect gas injector 252 described for embodiments of the present invention illustrated in FIG. 1, FIG. 2, or FIG. 3. Coanda effect gas injector 282 is similar to the at least one Coanda effect gas injector 252.

Coanda effect gas injector 282 is a substantially rigid structure having a gas entry port 253, a gas flow channel 254-2, and a gas exit port 255. Coanda effect gas injector 282 optionally has a plenum 256 that is not present in the at least one Coanda effect gas injectors 252. Gas exit port 255 is in fluid communication with plenum 256 via gas flow channel 254-2. Gas entry port 253 is in fluid communication with plenum 256. Gas flow channel 254-2 is formed by at least one convex surface 254-1 of Coanda effect gas injector 282 so as to produce the Coanda effect gas flow. Gas flow channel 254-2 for Coanda effect gas injector 282 has flared sidewalls that diverge to increase the width of gas flow channel 254-2 in the direction for gas flow. One of the potential benefits of this arrangement is that the width of gas exit port 255 can be made larger for use with a plenum having smaller dimensions and/or using a smaller structure for portions of the gas injector. Optionally, the flared sidewalls may be straight sidewalls that are angled to diverge, concave curved sidewalls, or convex curved sidewalls. Having flared sidewalls that are convex could produce a second Coanda effect on the gas exiting the Coanda effect gas injector 282.

During operation, Coanda effect gas injector 282 receives a gas or a mixture of gases at gas entry port 253, the gas flows into plenum 256 from gas entry port 253 and continues on into gas flow channel 254, passes over convex surface 254-1 while expanding in width determined by flared sidewalls of gas flow channel 254-2, and exits at gas exit port 255.

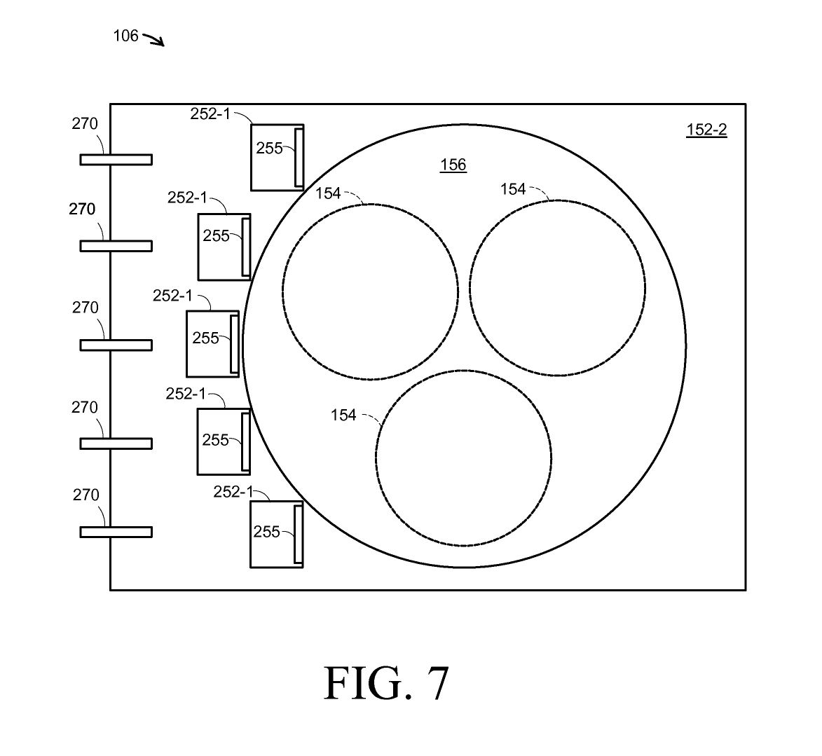

Reference is now made to FIG. 7 where there is shown a cross-section top view of a system 106 according to an embodiment of the present invention. Specifically, FIG. 7 shows the interior from a top view. System 106 comprises a process chamber that includes a bottom surface 152-2 and a top surface (the top surface is not shown in FIG. 7). System 106 includes a substrate holder 156 disposed so as to hold one or more substrates 154 in the process chamber. FIG. 7, as an example, uses broken lines to illustrate how three substrates 154 can be positioned for processing on substrate holder 156. As an option for some embodiments of the present invention, bottom surface 152-2 of the process chamber has a recessed area (not shown in FIG. 7) that at least partially contains substrate holder 156.

System 106, as an option for some embodiments of the present invention, comprises a rotary coupling (not shown in FIG. 7) connected with substrate holder 156 so as to provide rotation for the one or more substrates 154. More specifically, system 106 comprises an optional rotary coupling disposed between substrate support 156 and the process chamber for rotating the surface of substrate support 156 and the one or more substrates 154, if present thereon. Alternatively, system 106 may comprise a linear actuator connected with substrate support 156 for linear translation of the surface of substrate support 156.

System 106 comprises at least one Coanda effect gas injector 252-1 disposed proximate a peripheral edge of substrate support 156 so as to provide a Coanda effect gas flow over the surface of substrate support 156 and/or the one or more substrates 154. FIG. 7 shows five Coanda effect gas injectors 252-1. According to some embodiments of the present invention, system 106 further comprises a gas flow control system (not shown in FIG. 7) in fluid communication with the at least one Coanda effect gas injector 252-1 so as to provide one or more reactive gases to the at least one Coanda effect gas injector 252-1.

Coanda effect gas injector 252-1 is essentially the same as described above in FIG. 4. Alternatively, system 106 may comprise one or more or combinations of Coanda effect gas injectors such as Coanda effect gas injector 252, Coanda effect gas injector 272, and Coanda effect gas injector 282 as described above in FIG. 1, FIG. 5, and FIG. 6, respectively.

System 106 comprises at least one secondary gas injector 270 disposed so as to provide one or more gases or gas mixtures over bottom surface 152-2 of the process chamber. More specifically, the at least one secondary gas injector 270 is arranged to flow a gas or gas mixture over substrates 154 and/or substrate holder 156. FIG. 7 has five secondary gas injectors 270. The at least one secondary gas injector 270 is not a Coanda effect gas injector. The secondary gas injectors 270 may be standard gas injectors such as those typically used for processing substrates such as a solid body having a borehole for gas flow therethrough, such as a tube, such as a tube having a showerhead or nozzle, or such as another type of nozzle.

System 106 shows an embodiment with the at least one secondary gas injector 270 positioned behind the at least one Coanda effect gas injector 252-1. It is to be understood that other embodiments of the present invention may have relative positions and orientations of the at least one secondary gas injector 270 and the at least one Coanda effect gas injector 252-1 different from the arrangement shown in FIG. 7.

A potential benefit may be achieved for some embodiments of the present invention as a result of combining the use of the at least one Coanda effect gas injector 252-1 and the at least one secondary injector 270. In other words, a synergistic interaction between the gas flow from the at least one Coanda effect gas injector 252-1 and the gas flow from the at least one secondary injector 270 may yield improved process results.

As an option for some embodiments of the present invention, system 106 may further comprise a heating system for processing substrates at elevated temperatures (heating system not shown in FIG. 7). The heating system may be a hot wall heating system disposed so as to heat the substrates 154, the substrate holder 156, and the walls of the process chamber including bottom surface 152-2. Alternatively, the heating system may be a cold wall heating system disposed so as to substantially only heat the substrates 154 and/or the substrate holder 156 without substantial heating of the walls of the process chamber. A potential benefit for some embodiments of the present invention is that the Coanda effect gas flow could mitigate some of the effects of temperature-induced convection caused by variations in gas temperatures above the substrates.

For some embodiments of the present invention, the system such as system 100, system 102, system 104, and system 106, the process chamber, the substrate support, and the Coanda effect gas injectors comprise materials suitable for processing semiconductor devices. Examples of materials suitable for use with embodiments of the present invention include, but are not limited to, aluminum oxide, aluminum nitride, silicon carbide, silicon nitride, silicon dioxide such as quartz or fused silica, stainless steel, graphite, and silicon carbide coated graphite.

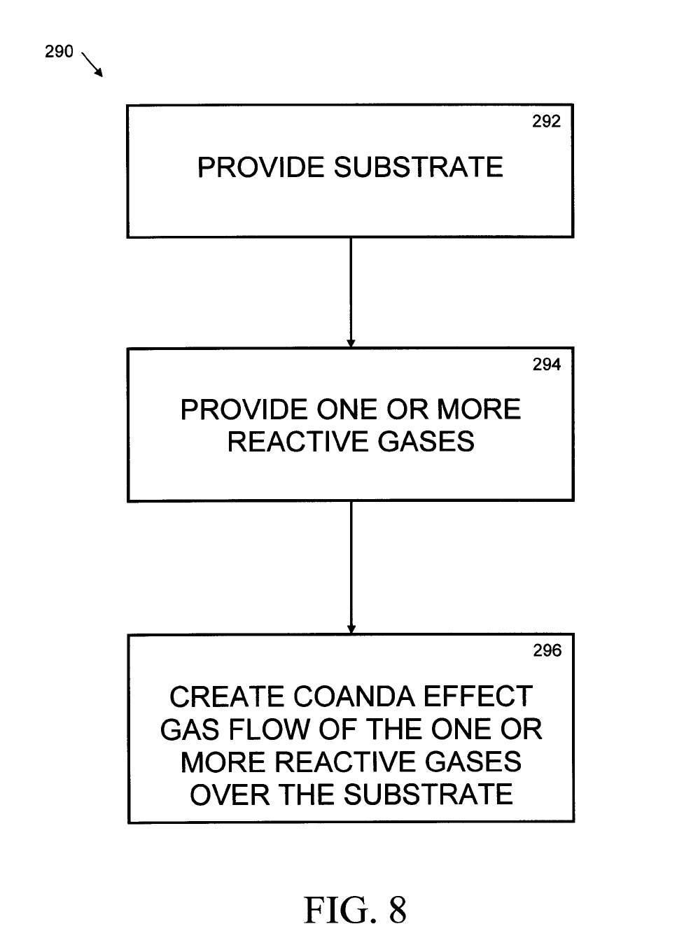

The systems and apparatuses described supra may be used for a wide variety of processes according to embodiments of the present invention. Reference is now made to FIG. 8 where there is shown an exemplary process diagram 290 according to one embodiment of the present invention. Exemplary process diagram 290 comprises a non-exhaustive series of steps to which additional steps (not shown) may also be added. One of ordinary skill in the art would recognize many variations, modifications, and alternatives. FIG. 8 shows exemplary process diagram 290 for performing a chemical reaction on a substrate comprising providing a substrate 292 and providing one or more reactive gases 294. Exemplary process diagram 290 further comprises creating a Coanda effect gas flow of the one or more reactive gases over the substrate 296 while maintaining conditions sufficient to cause the chemical reaction to occur.

As an option, exemplary process diagram 290 may also include one or more modifications for additional embodiments of the present invention. Exemplary modifications may include, but are not limited to, the following: Rotating the substrate while performing the chemical reaction (i.e., during 296). Providing the substrate 292 comprises providing a semiconductor wafer. Providing the substrate 292 comprises providing a substrate for fabricating electronic or optoelectronic devices. Providing the substrate 292 comprises providing a silicon wafer. Providing the one or more reactive gases 294 comprises providing one or more precursors for semiconductor deposition. Providing the one or more reactive gases 294 comprises providing a silicon precursor. Providing the one or more reactive gases 294 comprises providing a compound selected from the group consisting of silane, dichlorosilane, trichlorosilane, and silicon tetrachloride. Providing the one or more reactive gases 294 comprises providing a dopant compound for a semiconductor. Providing the one or more reactive gases 294 comprises providing one or more precursors for deposition of Group IV element semiconductors, Group IV element compound semiconductors, Group III-V element semiconductors, or Group II-VI element semiconductors. Creating the Coanda effect gas flow of the one or more reactive gases over the substrate 296 while maintaining conditions sufficient to cause the chemical reaction to occur comprises conditions for deposition of epitaxial silicon. Creating the Coanda effect gas flow of the one or more reactive gases over the substrate 296 while maintaining conditions sufficient to cause the chemical reaction to occur comprises conditions for deposition of an epitaxial layer of materials such as, but not limited to, cadmium telluride, cadmium mercury telluride, gallium arsenide, gallium nitride, indium antimonide, indium phosphide, silicon, silicon germanium, and silicon carbide.

Clearly, embodiments of the present invention can be used for a wide variety of processes such as those for semiconductor device fabrication. Changes in the selected process gases and process conditions allow embodiments of the present invention to include substrate processes such as deposition processes for epitaxial layers, polycrystalline layers, nanocrystalline layers, or amorphous layers; processes such as substrate etching or cleaning; substrate oxidation; and/or substrate doping.

Embodiments of the present invention also include methods and apparatus for growing layers of materials such as elemental materials, compounds, compound semiconductors, and compound dielectric materials. In preferred embodiments for compound semiconductor applications, at least one of the Coanda effect gas injectors is connected so as to provide a flow of a gas comprising at least one of the elements boron, aluminum, gallium, indium, carbon, silicon, germanium, tin, lead, nitrogen, phosphorus, arsenic, antimony, sulfur, selenium, tellurium, mercury, cadmium, and zinc. Optionally, one or more Coanda effect gas injectors and/or one or more secondary gas injectors is connected so as to provide a flow of a gas or gas mixture such as hydrogen; an inert gas; hydrogen mixed with a dopant; or an inert gas mixed with a dopant.

Methods according to embodiments of the present invention may include the use of a variety of process gases such as those described above. The gases used for the method will depend on the process. In one embodiment, the gas flow streams comprise silicon source gas, dopant gas, and hydrogen.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

As used herein, the terms “comprises,” “comprising,” “includes,” “including,” “has,” “having,” “at least one of,” or any other variation thereof, are intended to cover a non-exclusive inclusion. For example, a process, method, article, or apparatus that comprises a list of elements is not necessarily limited only to those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

While there have been described and illustrated specific embodiments of the invention, it will be clear that variations in the details of the embodiments specifically illustrated and described may be made without departing from the true spirit and scope of the invention as defined in the appended claims and their legal equivalents.

What is claimed is:

1. A system for processing substrates, the system comprising:
a process chamber;
a substrate support disposed in the process chamber; and
at least one Coanda effect gas injector disposed proximate a peripheral edge of the substrate support so as to provide a Coanda effect gas flow over the surface of the substrate support and/or the substrates.

2. The system of claim 1, wherein the at least one Coanda effect gas injector has a gas exit port, a gas flow channel, and a gas entry port; the gas exit port is in fluid communication with the gas flow channel, the gas flow channel is in fluid communication with the gas entry port; the gas flow channel is formed by at least one convex surface of the Coanda effect gas injector to produce the Coanda effect gas flow.

3. The system of claim 1, wherein the at least one Coanda effect gas injector has a gas entry port, a plenum, a gas flow channel, and a gas exit port; the gas exit port is in fluid communication with the plenum via the gas flow channel, the gas entry port is in fluid communication with the plenum, the gas flow channel is formed by at least one convex surface of the Coanda effect gas injector so as to produce the Coanda effect gas flow.

4. The system of claim 1, further comprising a rotary coupling connected with the substrate support and the process chamber for rotating the surface of the substrate support.

5. The system of claim 1, further comprising a linear actuator connected with the substrate support and the process chamber for linear translation of the surface of the substrate support.

6. The system of claim 1, further comprising a gas flow control system coupled so as to provide one or more reactive gases to the at least one Coanda effect gas injector.

7. The system of claim 1, wherein the gas exit port is substantially coplanar with or above the surface of the substrate.

8. The system of claim 1, wherein the gas exit port is substantially coplanar with or above the surface of the substrate support.

9. The system of claim 1, wherein the gas exit port is substantially coplanar with or above the bottom surface of the process chamber.

10. The system of claim 1, wherein the process chamber is a hot wall chamber for elevated temperature processes.

11. The system of claim 1, wherein the process chamber, the substrate support, and the Coanda effect gas injector comprise materials suitable for processing semiconductor devices.

12. The system of claim 1, wherein the process chamber, the substrate support, and the at least one Coanda effect gas injector comprise materials selected from the group consisting of aluminum oxide, aluminum nitride, silicon carbide, silicon nitride, silicon dioxide, stainless steel, graphite, and silicon carbide coated graphite.

13. The system of claim 1, wherein the at least one Coanda effect gas injector comprises a plurality of Coanda effect gas injectors.

14. The system of claim 1, wherein the at least one Coanda effect gas injector comprises five Coanda effect gas injectors.

15. The system of claim 1, wherein the at least one Coanda effect gas injector has a gas exit port, a gas flow channel, a plenum, and a gas entry port in fluid communication; the gas flow channel is formed by a convex surface of the at least one Coanda effect gas injector to produce the Coanda effect gas flow and the gas exit port extends completely over the convex surface.

16. The system of claim 1, wherein the at least one Coanda effect gas injector has a gas exit port, a gas flow channel, a plenum, and a gas entry port in fluid communication; the gas flow channel is formed by a convex surface of the Coanda effect gas injector to produce the Coanda effect gas flow and the gas flow channel has flared side walls.

17. The system of claim 1, further comprising a secondary gas injector disposed so as to provide a gas flow to the process chamber.

18. A method of performing a chemical reaction on a substrate, the method comprising:
providing a substrate;
providing one or more reactive gases; and
creating a Coanda effect gas flow of the one or more reactive gases over the substrate while maintaining conditions sufficient to cause the chemical reaction.

19. The method claim 18, further comprising rotating the substrate while performing the chemical reaction.

20. The method claim 18, wherein the providing the substrate comprises providing a semiconductor wafer.

21. The method claim 18, wherein the providing the substrate comprises providing a substrate for fabricating electronic or optoelectronic devices.

22. The method claim 18, wherein the providing the substrate comprises providing a silicon wafer.

23. The method claim 18, wherein the providing the one or more reactive gases comprises providing one or more precursors for semiconductor deposition.

24. The method claim 18, wherein the providing the one or more reactive gases comprises providing a silicon precursor.

25. The method claim 18, wherein the providing the one or more reactive gases comprises providing a compound selected from the group consisting of silane, dichlorosilane, trichlorosilane, and silicon tetrachloride.

26. The method claim 18, wherein the providing the one or more reactive gases comprises providing a dopant compound for a semiconductor.

27. The method claim 18, wherein the maintaining conditions sufficient to cause the chemical reaction to occur comprises conditions for deposition of epitaxial silicon.

28. The method claim 18, wherein the providing one or more reactive gases comprises providing one or more precursors for deposition of group IV element semiconductors, group IV element compound semiconductors, group III-V element semiconductors, or group II-VI element semiconductors.

29. The method claim 18, wherein the maintaining conditions sufficient to cause the chemical reaction to occur comprises conditions for deposition of an epitaxial layer.
